(19) United States
(12) Patent Application Publication
(10) Pub. No.: US 2020/0186152 A1
(43) Pub. Date: Jun. 11, 2020

(54) PHASE LOCKED LOOP

(71) Applicant: SK hynix Inc., Gyeonggi-do (KR)

(72) Inventors: Dong Seok KIM, Gyeonggi-do (KR); Minsoon HWANG, Gyeonggi-do (KR)

(21) Appl. No.: 16/507,897

(22) Filed: Jul. 10, 2019

(30) Foreign Application Priority Data
Dec. 5, 2018 (KR) 10-2018-0155140

(51) Int. Cl. H03L 7/081; H03L 7/089; H03L 7/099

(52) U.S. Cl. CPC H03L 7/081; H03L 7/099; H03L 7/0891

(57) ABSTRACT

A phase locked loop includes a phase adjustment circuit configured to detect a phase difference of an input signal and a feedback signal, and generate a pre-phase locked clock signal corresponding to the detected phase difference; and a multiple output synchronization circuit configured to generate a first phase locked clock signal by using the pre-phase locked clock signal, and generate a second phase locked clock signal which is synchronized with the first phase locked clock signal, by delaying the pre-phase locked clock signal by a signal processing time for generating the first phase locked clock signal.

### CROSS-REFERENCES TO RELATED APPLICATION

The present application claims priority under 35 U.S.C. § 119(a) to Korean application number 10-2018-0155140, filed on Dec. 5, 2018, which is incorporated herein by reference in its entirety.

### BACKGROUND

### 1. Technical Field

Various embodiments of the present disclosure generally relate to a semiconductor circuit. Particularly, the embodiments relate to a phase locked loop.

### 2. Related Art

Generally, an electronic system includes circuits including a phase locked loop (PLL). The phase locked loop continuously compares the phases of a reference signal and an output signal, corrects a frequency based on a result thereof and outputs the output signal having a constant frequency.

A phase locked loop may be designed to generate multiple output signals having different frequencies, depending on a system to which it is applied.

### SUMMARY

Various embodiments are directed to a phase locked loop capable of synchronizing multiple output signals with an input signal.

In an embodiment, a phase locked loop may include: a phase adjustment circuit configured to detect a phase difference of an input signal and a feedback signal, and generate a pre-phase locked clock signal corresponding to the detected phase difference; and a multiple output synchronization circuit configured to generate a first phase locked clock signal by using the pre-phase locked clock signal, and generate a second phase locked clock signal which is synchronized with the first phase locked clock signal, by delaying the pre-phase locked clock signal by a signal processing time for generating the first phase locked clock signal.

In an embodiment, a phase locked loop may include: a phase adjustment circuit configured to detect a phase difference of an input signal and a feedback signal, and generate a pre-phase locked clock signal corresponding to the detected phase difference; a divider configured to generate a first phase locked clock signal by dividing a frequency of the pre-phase locked clock signal into a preset division ratio; and a replica delay, as a replica delay circuit modeling the divider, configured to generate a second phase locked clock signal by delaying the pre-phase locked clock signal by a signal delay time according to a dividing operation of the divider.

In an embodiment, a phase locked loop may include: a phase frequency detection circuit configured to compare phases of an input signal and a feedback signal and thereby detect a phase difference therebetween, and generate a comparison result signal depending on the detected phase difference; a charge pump configured to generate a control voltage corresponding to the comparison result signal; a voltage-controlled oscillation circuit configured to generate a pre-phase locked clock signal of which a frequency varies in correspondence to the control voltage; a divider configured to generate a first phase locked clock signal by dividing a frequency of the pre-phase locked clock signal into a preset division ratio; and a replica delay, as a replica delay circuit modeling the divider, configured to generate a second phase locked clock signal by delaying the pre-phase locked clock signal by a signal delay time according to a dividing operation of the divider.

### BRIEF DESCRIPTION OF THE DRAWINGS

FIG. 1 is a diagram illustrating a phase locked loop in accordance with an embodiment.

FIG. 2 is a diagram illustrating a phase frequency detection circuit in accordance with an embodiment.

FIG. 3 is a diagram illustrating a voltage controlled oscillation circuit in accordance with an embodiment.

FIG. 4 is a diagram illustrating a multiple output synchronization circuit in accordance with an embodiment.

FIG. 5 is a diagram illustrating a divider and a replica delay in accordance with an embodiment.

### DETAILED DESCRIPTION

Various embodiments of the present invention are described below in more detail with reference to the accompanying drawings. We note, however, that the present invention may be embodied in different forms and variations, and should not be construed as being limited to the embodiments set forth herein. Rather, the described embodiments are provided so that this disclosure will be thorough and complete, and will fully convey the present invention to those skilled in the art to which this invention pertains. Throughout the disclosure, like reference numerals refer to like parts throughout the various figures and embodiments of the present invention.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present. Communication between two elements, whether directly or indirectly connected/coupled, may be wired or wireless, unless stated or the context indicates otherwise.

As used herein, singular forms may include the plural forms as well and vice versa, unless the context clearly indicates otherwise. The articles ‘a’ and ‘an’ as used in this application and the appended claims should generally be construed to mean ‘one or more’ unless specified otherwise or clear from context to be directed to a singular form.

It is noted that reference to “an embodiment,” “another embodiment” or the like does not necessarily mean only one embodiment, and different references to any such phrase are not necessarily to the same embodiment(s).

Hereinafter, a phase locked loop will be described below with reference to the accompanying drawings through various examples of embodiments.

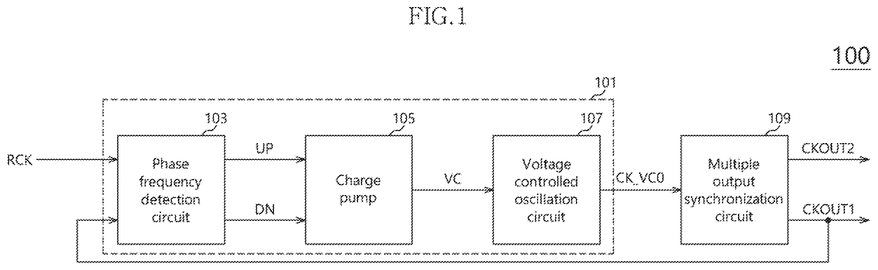

FIG. 1 is a diagram illustrating a phase locked loop 100 in accordance with an embodiment.

Referring to FIG. 1, the phase locked loop 100 may include a phase adjustment circuit 101 and a multiple output synchronization circuit 109.

The phase adjustment circuit 101 may detect the phase difference of an input signal and a feedback signal. Further, the phase adjustment circuit 101 may generate a pre-phase locked clock signal CK_VCO corresponding to the detected phase difference.

A reference clock signal RCK may be used as the input signal. A first phase locked clock signal CKOUT1 may be used as the feedback signal.

The phase adjustment circuit 101 may include a phase frequency detection circuit 103, a charge pump 105 and a voltage controlled oscillation circuit 107.

The phase frequency detection circuit 103 may compare the phases of the input signal and the feedback signal and thereby detect the phase difference thereof. Further, the phase frequency detection circuit 103 may generate comparison result signals UP and DN depending on the detected phase difference.

The phase frequency detection circuit 103 may generate the up signal UP of the comparison result signals UP and DN when the reference clock signal RCK leads the first phase locked clock signal CKOUT1.

The phase frequency detection circuit 103 may generate the down signal DN of the comparison result signals UP and DN when the reference clock signal RCK lags the first phase locked clock signal CKOUT1.

The charge pump 105 may generate a control voltage VC corresponding to the comparison result signal UP or DN.

The charge pump 105 may generate current corresponding to the comparison result signal UP or DN. The charge pump 105 may include a filter (for example, a low pass filter). The filter may convert the generated current into the control voltage VC and output the control voltage VC.

The voltage controlled oscillation circuit 107 may generate the pre-phase locked clock signal CK_VCO of which the frequency varies in correspondence to the control voltage VC.

The voltage controlled oscillation circuit 107 may generate the pre-phase locked clock signal CK_VCO depending on the control voltage VC. The pre-phase locked clock signal CK_VCO has a frequency greater than the frequency of the reference clock signal RCK. For example, the pre-phase locked clock signal CK_VCO has a frequency corresponding to two times or four times the frequency of the reference clock signal RCK.

The multiple output synchronization circuit 109 may generate the first phase locked clock signal CKOUT1 by using the pre-phase locked clock signal CK_VCO. Further, the multiple output synchronization circuit 109 may generate a second phase locked clock signal CKOUT2 by delaying the pre-phase locked clock signal CK_VCO. The second phase locked clock signal CKOUT2 may be synchronized with the first phase locked clock signal CKOUT1. The second phase locked clock signal CKOUT2 may be generated by delaying the pre-phase locked clock signal CK_VCO by a signal processing time for generating the first phase locked clock signal CKOUT1.

The multiple output synchronization circuit 109 may generate the first phase locked clock signal CKOUT1 by dividing the pre-phase locked clock signal CK_VCO. Further, the multiple output synchronization circuit 109 may generate the second phase locked clock signal CKOUT2 by delaying the pre-phase locked clock signal CK_VCO. The second phase locked clock signal CKOUT2 may be synchronized with the first phase locked clock signal CKOUT1. The second phase locked clock signal CKOUT2 may be generated by delaying the pre-phase locked clock signal CK_VCO by a delay time according to the dividing operation.

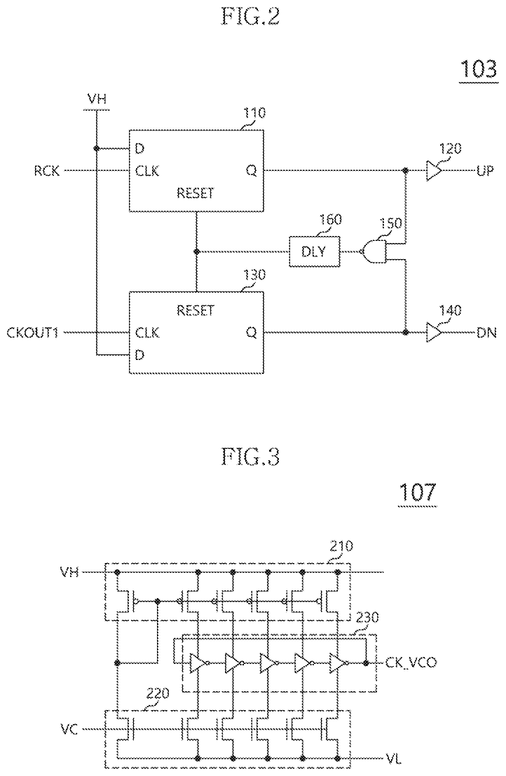

FIG. 2 is a diagram illustrating a phase frequency detection circuit in accordance with an embodiment, for example, the phase frequency detection circuit 103 illustrated in FIG. 1.

Referring to FIG. 2, the phase frequency detection circuit 103 may include a first flip-flop 110, a first buffer 120, a second flip-flop 130, a second buffer 140, a NAND gate 150 and a delay (DLY) 160.

The first flip-flop 110 may latch and output the level (for example, a high level) of a first power terminal VH depending on the reference clock signal RCK.

The first buffer 120 may output the output of the first flip-flop 110 as the up signal UP.

The second flip-flop 130 may latch and output the level of the first power terminal VH depending on the first phase locked clock signal CKOUT1.

The second buffer 140 may output the output of the second flip-flop 130 as the down signal DN.

The NAND gate 150 may perform a NAND logic function on the output of the first flip-flop 110 and the output of the second flip-flop 130, and may output an output.

The delay 160 may delay the output of the NAND gate 150 by a predetermined time. Further, the delay 160 may output the delayed output to reset terminals RESET of the first flip-flop 110 and the second flip-flop 130.

FIG. 3 is a diagram illustrating a voltage controlled oscillation circuit in accordance with an embodiment, for example, the voltage-controlled oscillation circuit 107 illustrated in FIG. 1.

Referring to FIG. 3, the voltage controlled oscillation circuit 107 may include a first transistor array 210, a second transistor array 220 and an inverter array 230.

The first transistor array 210 may include a plurality of PMOS transistors in parallel. The plurality of PMOS transistors may have source terminals which are coupled in common with the first power terminal VH and gate terminals which are coupled in common with a drain terminal of one PMOS transistor among the plurality of PMOS transistors.

The second transistor array 220 may include a plurality of NMOS transistors in parallel. The plurality of NMOS transistors may have source terminals which are coupled in common with a second power terminal VL and gate terminals to which the control voltage VC is applied in common.

The inverter array 230 may include a plurality of inverters in series. The plurality of inverters may be coupled with the first power terminal VH through the first transistor array 210, and may be coupled with the second power terminal VL through the second transistor array 220. The inverter array 230 may operate as an oscillator which generates a pulse signal periodically repeated as a signal generated at an output terminal is fed back to an input terminal.

A power supply voltage of the first power terminal VH may be greater than a power supply voltage of the second power terminal VL.

In the voltage controlled oscillation circuit 107, an amount of current is supplied to each of the inverters of the inverter array 230. The amount of current may vary depending on the level of the control voltage VC, and accordingly, the delay time of each inverter may vary.

For example, as the level of the control voltage VC increases, an amount of current supplied to each inverter increases, and accordingly, the delay time of each inverter becomes shorter. As the delay time of each inverter becomes shorter, the frequency of the output signal of the inverter array 230, that is, the pre-phase locked clock signal CK_VCO, increases.

Conversely, as the level of the control voltage VC decreases, an amount of current supplied to each inverter decreases, and accordingly, the delay time of each inverter becomes longer. As the delay time of each inverter becomes longer, the frequency of the pre-phase locked clock signal CK_VCO decreases.

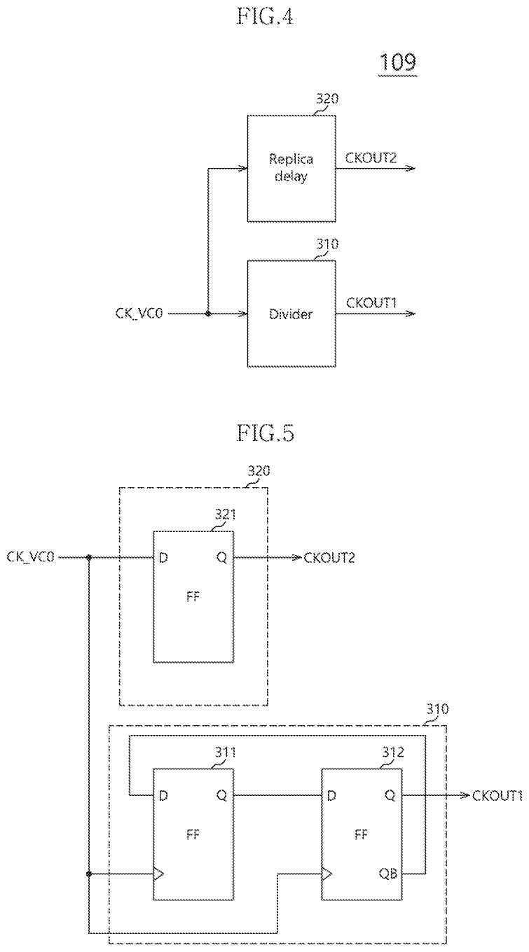

FIG. 4 is a diagram illustrating a multiple output synchronization circuit in accordance with an embodiment, for example, the multiple output synchronization circuit 109 illustrated in FIG. 1.

Referring to FIG. 4, the multiple output synchronization circuit 109 may include a divider 310 and a replica delay 320.

The divider 310 may receive the pre-phase locked clock signal CK_VCO and generate the first phase locked clock signal CKOUT1. In various embodiments, he divider 310 may generate the first phase locked clock signal CKOUT1 by dividing the frequency of the pre-phase locked clock signal CK_VCO into a preset division ratio (for example, 2 or 4).

As described above, the pre-phase locked clock signal CK_VCO has a frequency greater than the frequency of the reference clock signal RCK, for example, a frequency corresponding to two times or four times the frequency of the reference dock signal RCK. Thus, the divider 310 may divide the frequency of the pre-phase locked clock signal CK_VCO into a preset division ratio (for example, 2 or 4), and may generate the first phase locked clock signal CKOUT1, which has the same frequency as the reference clock signal RCK.

The replica delay 320 as a replica delay circuit modeling the divider 310 may generate the second phase locked clock signal CKOUT2. In various embodiments, the replica delay 320 may generate the second phase locked clock signal CKOUT2 by delaying the pre-phase locked clock signal CK_VCO by a signal processing delay time according to the dividing operation of the divider 310.

The second phase locked clock signal CKOUT2 may have a frequency different from the frequency of the reference clock signal RCK. For example, the second phase locked clock signal CKOUT2 may have a frequency corresponding to two times or four times the frequency of the reference clock signal RCK.

FIG. 5 is a diagram illustrating a divider and a replica delay in accordance with an embodiment, for example, the divider 310 and the replica delay 320 illustrated in FIG. 4.

Referring to FIG. 5, the divider 310 may include a first flip-flop 311 and a second flip-flop 312 in series.

The first flip-flop 311 may have a clock terminal which receives the pre-phase locked clock signal CK_VCO.

The second flip-flop 312 may have a clock terminal which receives the pre-phase locked clock signal CK_VCO, an input terminal D which is coupled with an output terminal Q of the first flip-flop 311, an inverting output terminal QB which is coupled with an input terminal D of the first flip-flop 311, and an output terminal Q which outputs the first phase locked clock signal CKOUT1.

The divider 310 may output the signal obtained by dividing the pre-phase locked clock signal CK_VCO into the preset division ratio (for example, 4), as the first phase locked clock signal CKOUT1. In various embodiments, the signal outputted from the inverting output terminal QB of the second flip-flop 312 is fed back to the input terminal D of the first flip-flop 311 depending on the pre-phase locked clock signal CK_VCO.

By the operation of the divider 310, the first phase locked clock signal CKOUT1 may have a delay time corresponding to the signal processing delay time of the first flip-flop 311 or the second flip-flop 312 when compared to the pre-phase locked clock signal CK_VCO.

The first flip-flop 311 and the second flip-flop 312 may have the same signal processing delay time (hereinafter, referred to as a first delay time).

As described above, the replica delay 320 may delay the pre-phase locked clock signal CK_VCO by the signal processing delay time according to the dividing operation of the divider 310, that is, the first delay time.

Because the first phase locked clock signal CKOUT1 is delayed by the first delay time when compared to the pre-phase locked clock signal CK_VCO, the replica delay 320 may include a flip-flop 321.

The flip-flop 321 may be configured in the same manner as the first flip-flop 311 or the second flip-flop 312 of the divider 310.

The flip-flop 321 has an input terminal D which receives the pre-phase locked clock signal CK_VCO and a clock terminal which does not receive a separate clock signal.

Thus, the flip-flop 321 may output the second phase locked clock signal CKOUT2 by not dividing the pre-phase locked clock signal CK_VCO but simply delaying the pre-phase locked clock signal CK_VCO by the first delay time.

The above-described configuration of the replica delay 320 is merely an example according to the configuration of the divider 310. As the configuration of the divider 310 is changed, the configuration of the replica delay 320 may also be changed.

For example, if the divider 310 is designed such that the first phase locked clock signal CKOUT1 has a delay time corresponding to the signal processing delay time of two flip-flops when compared to the pre-phase locked clock signal CK_VCO, the replica delay 320 may be designed to include two flip-flops.

The operation of the phase locked loop 100, configured as mentioned above, will be described below.

The first phase locked clock signal CKOUT1 and the second phase locked clock signal CKOUT2 may be generated through the phase frequency detection circuit 103, the charge pump 105, the voltage controlled oscillation circuit 107 and the multiple output synchronization circuit 109 depending on the reference clock signal RCK and the feedback signal.

The second phase locked dock signal CKOUT2 may have a phase difference from the first phase locked clock signal CKOUT1 due to the signal processing delay of the divider 310.

Therefore, in the embodiment, by delaying the second phase locked clock signal CKOUT2 through the replica delay 320, the phase of the second phase locked clock signal CKOUT2 may be synchronized with the phase of the first phase locked clock signal CKOUT1.

The phase of the first phase locked clock signal CKOUT1 may be synchronized with the phase of the reference clock signal RCK as the input signal of the phase frequency detection circuit 103 by a repetitive phase matching operation through a closed loop, which includes the phase frequency detection circuit 103, the charge pump 105, the voltage-controlled oscillation circuit 107 and the multiple output synchronization circuit 109.

Accordingly, in the embodiment, the phases of the input signal (that is, the reference clock signal RCK) may be synchronized with the multiple output signals (that is, the first phase locked clock signal CKOUT1 and the second phase locked clock signal CKOUT2).

While various embodiments have been described above, it will be understood to those skilled in the art that the embodiments described are examples only. Accordingly, the phase locked loop described herein should not be limited based on the described embodiments.

What is claimed is:

1. A phase locked loop comprising:
a phase adjustment circuit configured to detect a phase difference of an input signal and a feedback signal, and generate a pre-phase locked clock signal corresponding to the detected phase difference; and
a multiple output synchronization circuit configured to generate a first phase locked clock signal and a second phase locked clock signal which is synchronized with the first phase locked clock signal, by delaying the pre-phase locked clock signal by a signal processing time for generating the first phase locked clock signal.

2. The phase locked loop according to claim 1, wherein one of the first phase locked clock signal and the second phase locked clock signal is provided as the feedback signal.

3. The phase locked loop according to claim 1,
wherein the first phase locked clock signal has a frequency the same as the input signal, and
wherein the second phase locked clock signal has a frequency different from the input signal.

4. The phase locked loop according to claim 1, wherein the phase adjustment circuit comprises:
a phase frequency detection circuit configured to compare phases of the input signal and the feedback signal and detect the phase difference therebetween, and generate a comparison result signal depending on the detected phase difference;
a charge pump configured to generate a control voltage corresponding to the comparison result signal; and
a voltage controlled oscillation circuit configured to generate the pre-phase locked clock signal of which a frequency varies in correspondence to the control voltage.

5. The phase locked loop according to claim 1, wherein the multiple output synchronization circuit comprises:
a divider configured to generate the first phase locked clock signal by dividing the frequency of the pre-phase locked clock signal into a preset division ratio; and
a replica delay, as a replica delay circuit modeling the divider, configured to generate the second phase locked clock signal by delaying the pre-phase locked clock signal by a signal delay time according to a dividing operation of the divider.

6. A phase locked loop comprising:
a phase adjustment circuit configured to detect a phase difference of an input signal and a feedback signal, and generate a pre-phase locked clock signal corresponding to the detected phase difference;
a divider configured to generate a first phase locked clock signal by dividing a frequency of the pre-phase locked clock signal into a preset division ratio; and
a replica delay, as a replica delay circuit modeling the divider, configured to generate a second phase locked clock signal by delaying the pre-phase locked clock signal by a signal delay time according to a dividing operation of the divider.

7. The phase locked loop according to claim 6, wherein one of the first phase locked clock signal and the second phase locked clock signal is provided as the feedback signal.

8. The phase locked loop according to claim 6,
wherein the first phase locked clock signal has a frequency the same as the input signal, and
wherein the second phase locked clock signal has a frequency different from the input signal.

9. The phase locked loop according to claim 6, wherein the phase adjustment circuit comprises:
a phase frequency detection circuit configured to compare phases of the input signal and the feedback signal and detect the phase difference therebetween, and generate a comparison result signal depending on the detected phase difference;
a charge pump configured to generate a control voltage corresponding to the comparison result signal; and
a voltage controlled oscillation circuit configured to generate the pre-phase locked clock signal of which a frequency varies in correspondence to the control voltage.

10. A phase locked loop comprising:
a phase frequency detection circuit configured to compare phases of an input signal and a feedback signal and detect a phase difference therebetween, and generate a comparison result signal depending on the detected phase difference;
a charge pump configured to generate a control voltage corresponding to the comparison result signal;
a voltage controlled oscillation circuit configured to generate a pre-phase locked clock signal of which a frequency varies in correspondence to the control voltage;
a divider configured to generate a first phase locked clock signal by dividing a frequency of the pre-phase locked clock signal into a preset division ratio; and
a replica delay, as a replica delay circuit modeling the divider, configured to generate a second phase locked clock signal by delaying the pre-phase locked clock signal by a signal delay time according to a dividing operation of the divider.

11. The phase locked loop according to claim 10, wherein one of the first phase locked clock signal and the second phase locked clock signal is provided as the feedback signal.

12. The phase locked loop according to claim 10,
wherein the first phase locked clock signal has a frequency the same as the input signal, and
wherein the second phase locked clock signal has a frequency different from the input signal.
